(19) United States
(12) Patent Application Publication
(10) Pub. No.: US 2024/0356300 A1
(43) Pub. Date: Oct. 24, 2024

(54) SEMICONDUCTOR WAFER FABRICATION

(71) Applicant: AMS SENSORS ASIA PTE. LTD., Singapore (SG)

(72) Inventors: Baiming GUO, Singapore (SG); Qing WANG, Plainsboro, NJ (US); Wei Ting CHEN, Cambridge, MA (US); Feng ZHAO, Eindhoven (NL); Alexander MIGLO, Eindhoven (NL); Jichi MA, Ithaca, NY (US); Guoyang XU, Newtown, PA (US)

(21) Appl. No.: 18/684,200

(22) PCT Filed: Jul. 19, 2022
(86) PCT No.: PCT/SG2022/050512

§ 371 Date: Feb. 16, 2024

(30) Foreign Application Priority Data
Aug. 15, 2021 (GB) 2111726.2

(51) Int. Cl. H01S 5/00; H01S 5/40; H01S 5/42

(52) U.S. Cl. CPC H01S 5/0042; H01S 5/4012; H01S 5/423

(57) ABSTRACT

A method of making an optical device. The method comprises providing a semiconductor wafer, providing an array of emitters located on a first side of the wafer and providing one or more optical components on a second, opposite side of the wafer, wherein the or each optical component is arranged to split light from an associated emitter of the array of emitters. The method further comprises emitting light with the associated emitter, receiving light emitted by the associated emitter and transmitted through the optical component on the second side of the wafer, and determining an alignment between the one or more optical components and the array of emitters from the received light.

### CROSS-REFERENCE TO RELATED APPLICATIONS

This is a national phase of PCT Application PCT/SG2022/050512, filed on Jul. 19, 2022, which claims priority to British Application GB 2111726.2, which was filed on Aug. 16, 2021, the entire contents of each of which are incorporated herein by reference.

### FIELD OF DISCLOSURE

The invention relates to semiconductor wafer fabrication and in particular to a fabrication process with improved alignment of components, for example by determining an alignment between emitters on one side of the wafer and optical components on the other side of wafer during the fabrication process.

### BACKGROUND

Vertical cavity surface emitting lasers (VCSELs) with integrated micro-optics is an important part of sensor technology. The typical structure of such a device consists of VCSEL emitters on one side (bonding side) of a wafer and micro-optics on the other side (on the light emission surface). For a device to function properly, the optics needs to be accurately aligned to the output beam from the emitters. In many cases, the requirements on the alignment are sub-micron or smaller, which can pose a great challenge for standard lithography processes.

Fiducial markers (a.k.a. fiducial marks) on both sides of the wafer may be used to align the emitters and optics to the markers on their respective sides. However, misalignment between the emitters and optics can still occur due to misalignment between the fiducial markers on one side with respect to the markers on the other side, or misalignment between the fiducial markers on one side and the emitters or optics on that side.

### SUMMARY

To at least partly solve this problem the present disclosure provides a solution in which one or more optical components are used to split the light transmitted through the wafer and thereby determine the alignment.

According to a first aspect of the present disclosure there is provided a method of making an optical device. The method comprises providing a semiconductor wafer (typically a GaAs substrate), providing an array of emitters (e.g. VCSELs) located on a first side of the wafer (e.g. on the so called “bottom emitter side”), and providing one or more optical components on a second, opposite side of the wafer (e.g. on the emission surface), wherein the or each optical components is arranged to split light from an associated emitter of the array of emitters. The emitters may be provided by an Epi process. The method further comprises emitting light with the associated emitter, receiving light emitted by the associated emitter and transmitted through the optical component on the second side of the wafer, and determining an alignment between the one or more optical components and the array of emitters from the received light.

Hence, the real alignment between the emitters on one side of the wafer with optical components fabricated on the other side can be evaluated independently of any fiducial markers used when fabricating the emitters and the optical components. The solution may also be applied to passive optical devices, which do not comprise the array of emitters but instead an array of apertures for transmitting light from the first side of the wafer to second side and through the optics. In that case, the method can be used to determine the alignment between the apertures and the optical components. Using multiple optical components can improve the signal to noise ratio (SNR) of the alignment measurement. “Splitting” the light should be construed in broad sense and encompasses diffracting the beam to form side lobes and mode converting the beam to form multiple intensity peaks.

According to a second aspect of the present disclosure there is provided another method of making an optical device. The method comprises providing a semiconductor wafer, providing an array of apertures located on a first side of the wafer and providing one or more optical components on a second, opposite side of the wafer, wherein the or each optical component is arranged to split light transmitted through an associated aperture of the array of apertures. The method further comprises emitting light (e.g. using a monochromatic plane wave light source located on the first side of the wafer) through the associated aperture from the first side of the wafer, receiving light transmitted through the associated aperture and through the optical component on the second side of the wafer, and determining an alignment between the one or more optical components and the array of apertures from the received light.

The method according to the first or second aspect may further comprise adjusting a position of a fabrication tool relative to the wafer based on the determined alignment, and fabricating with the fabrication tool an array of optical elements on the second side of the wafer and aligned with the array of emitters or apertures on the first side of the wafer. For example, the wafer may be placed on a wafer chuck or in a holder of a lithography tool for lithographically fabricating the array of optical elements, and the position of the wafer or the mask or the holder may then be adjusted based on the determined alignment to correctly align the emitters or apertures with the optical elements.

The method may further comprise, before the step of determining the alignment, fabricating with a fabrication tool an array of optical elements on the second side of the wafer and aligned with the array of emitters or apertures on the first side of the wafer. The array of optical elements may be micro- or nano-optic elements, which are part of the final optical device.

The method may be repeated to provide a plurality of optical devices on respective semiconductor wafers and, after the step of determining, if the alignment of a wafer is below a predetermined threshold value, one or more dies or the whole wafer may be discarded. Hence, the method may be used for quality control to check the alignment after the wafer has been populated with the optical elements.

The or each optical component may comprise an optical quadrant component for separating the emitted light into four beams. That is, as the light is transmitted through the optical component it is separated s into four separate beams. The intensities/amplitudes of the four beams can then be compared to determine the alignment of the optical element with respect to the emitter/aperture. The quadrant component may comprise a quadrant prism. A quadrant prism is a type of quad prism in which the four separator elements are arranged as quadrants. The quadrant prism can be refractive, diffractive or a metaprism. A CCD or CMOS camera can be used to measure the transmitted light pattern for calculating the misalignment.

A diffraction element may also be used to measure the alignment. For example, the optical component may comprise a transparent or opaque crossing pattern. For example, the optical component may comprise a diffracting element comprising an opaque square with a transparent cross, or the optical component may comprise a diffracting element comprising a transparent square with an opaque cross.

Alternatively, the optical components may comprise a metasurface comprising nanowires arranged to mode convert at least a part of the emitted light from a first mode to a second mode. For example, the emitters typically emit light primarily in the TEM₀₀ mode (the fundamental mode, having a single central peak). Nanowires can be arranged to convert some of the light to the higher mode TEM₁₁, which has four peaks. The relative intensity of the four peaks can then be evaluated to determine the alignment between the nanowire structure and the emitter. For example, a camera with a polarisation analyser can be used to image the TEM₁₁ mode.

The zero-order beam from a diffractive element, or from the metasurface, or the direct pass through beam from the imperfect zone of a quadrant component can introduce error in the alignment measurement. Therefore, minimum zero order light from the optical component is beneficial. Larger-angle deflected beams can be used to avoid the zero-order beam in the far field quadrant beams.

At least two optical components may be provided and the step of determining an alignment may then comprise determining a rotational alignment between the array of emitters or apertures and the optical components. A single optical component can be used to determine lateral/horizontal alignment along the wafer plane, but with multiple optical components rotational alignment can also be determined.

The method may also comprise providing a first set of fiducial markers on the first side of the wafer, and a second set of fiducial markers on the second side of the wafer, wherein the step of providing the array of emitters or apertures comprises aligning the array of emitters or apertures with the first set of fiducial markers, and wherein the step of providing the one or more optical components comprises aligning the one or more optical components with the second set of fiducial markers. Hence, the fiducial markers are used to provide initial alignment between the emitters/apertures and the optical components on the other side of the wafer.

The method may further comprise dicing the wafer such that the one or more optical components are removed from the wafer. In general, the optical components used for alignment are not part of the final optical device.

According to a third aspect of the present disclosure there is provided a semiconductor wafer for making an optical device. The wafer comprises an array of emitters or apertures on a first side of the wafer and one or more optical components on a second, opposite side of the wafer, wherein the or each optical components is arranged to split light from an associated emitter or aperture of the array of emitters or apertures in order to determine an alignment between the one or more optical components and the array of emitters or apertures. The wafer may be provided according to the first or second aspect.

The or each optical component typically comprises one of a quadrant component, a diffractive element and a metasurface comprising nanowires.

### BRIEF DESCRIPTION OF THE PREFERRED EMBODIMENTS

Specific embodiments of the disclosure are described below with reference to the accompanying drawings, wherein

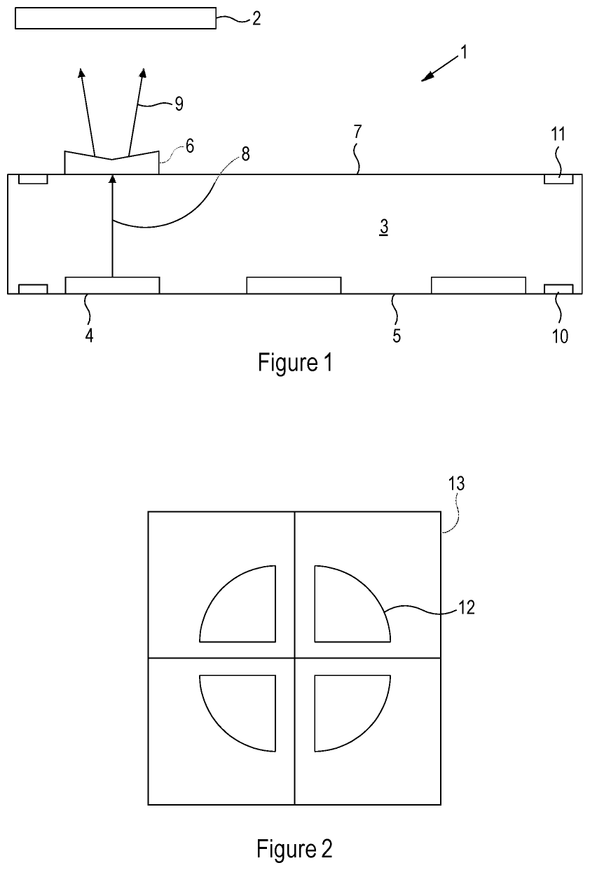

FIG. 1 shows a schematic diagram of a part of an optical device according to an embodiment;

FIG. 2 shows an intensity distribution of light after being split by quadrant optics;

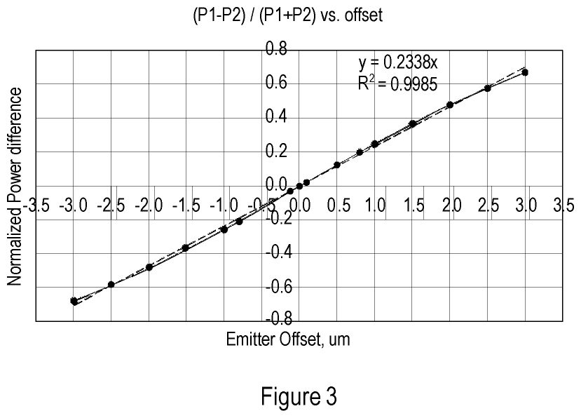

FIG. 3 shows a plot of the normalized power difference between two quadrants as a function of offset along one axis;

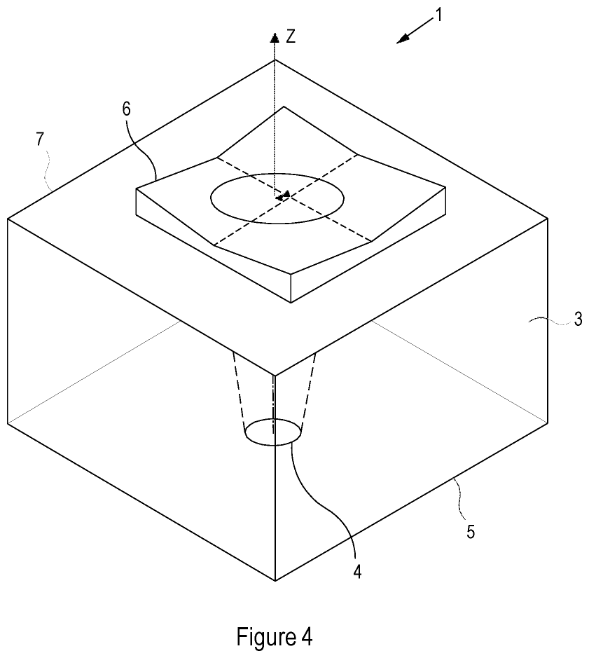

FIG. 4 shows a perspective view of a part of an optical device according to an embodiment comprising a quadrant prism;

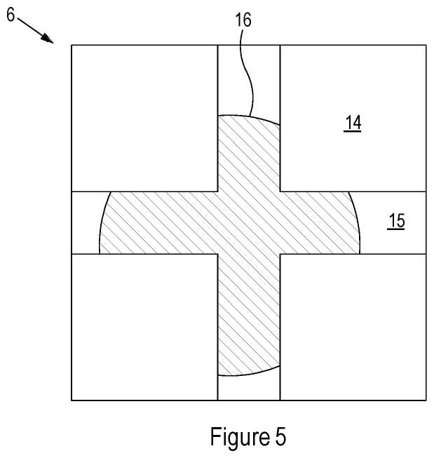

FIG. 5 shows an optical components comprising a diffractive element;

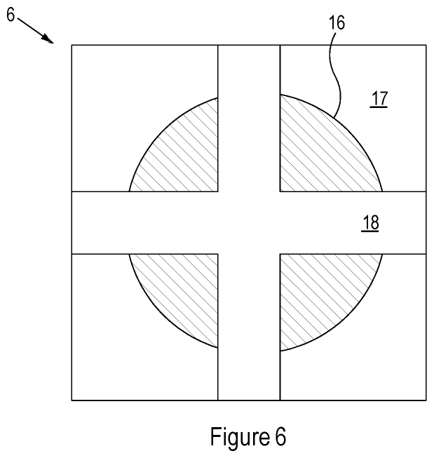

FIG. 6 shows another optical component comprising a diffractive element;

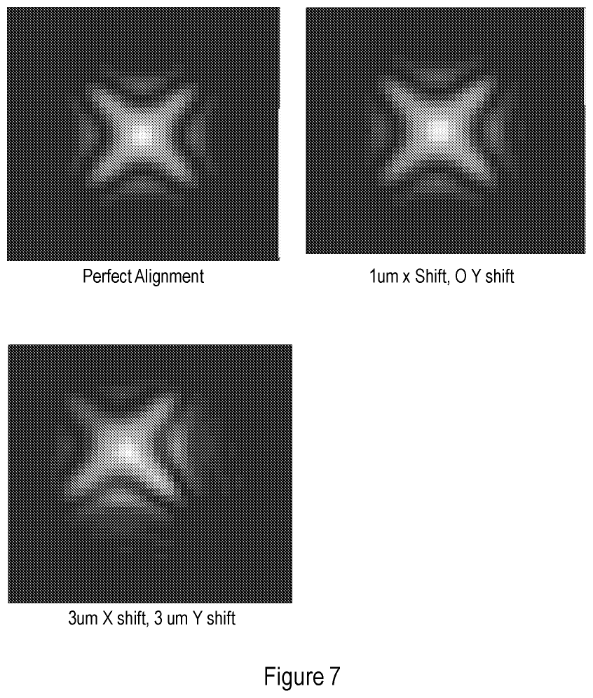

FIG. 7 shows graphs of 2D plots of the light distribution from a diffractive element for different offsets;

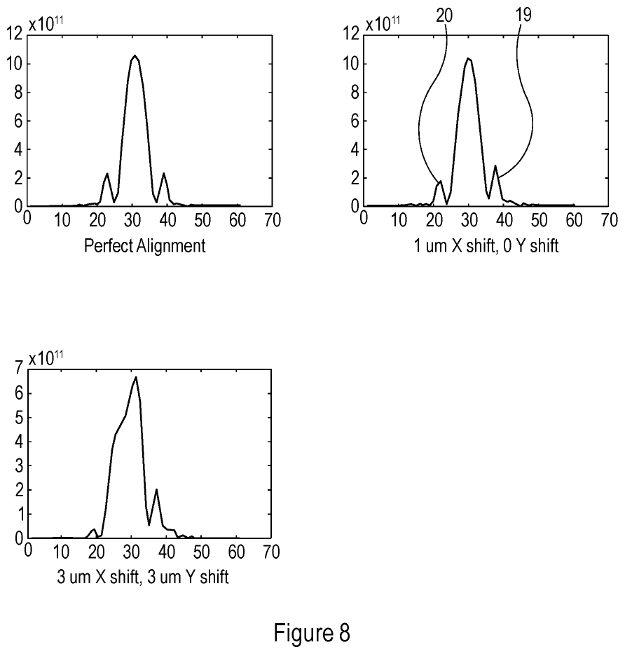

FIG. 8 shows line plots being cross sections of the 2D plots of FIG. 7;

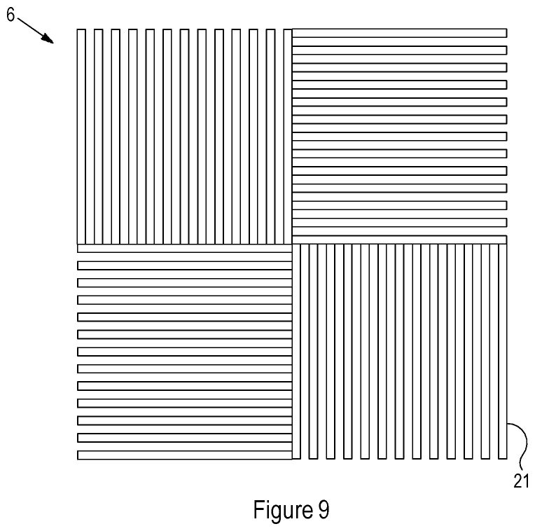

FIG. 9 shows an optical components comprising nanowires;

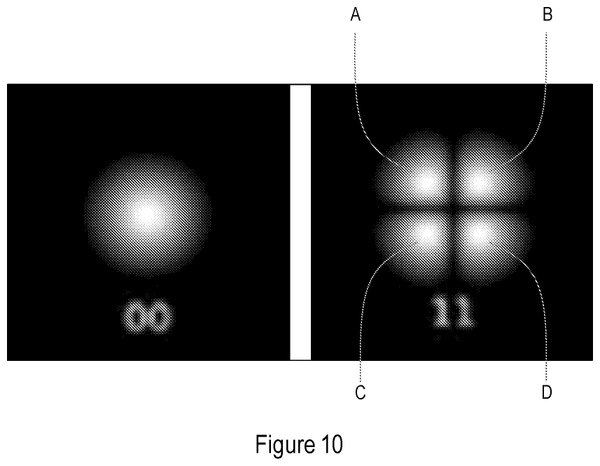

FIG. 10 shows the TEM₀₀ mode and the TEM₁₁ mode of a laser beam;

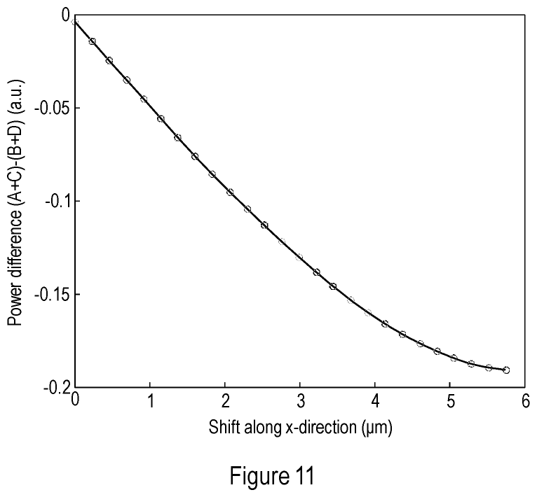

FIG. 11 shows a plot of the power difference between peaks of the TEM₁₁ mode as a function of offset;

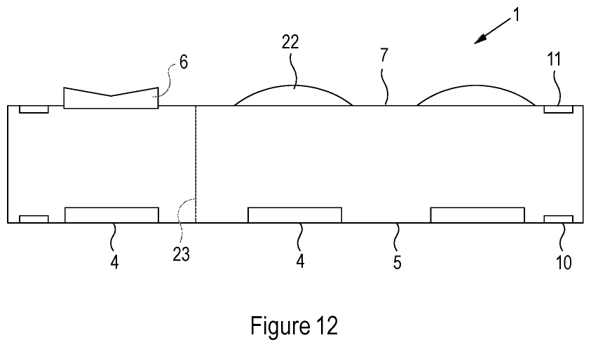

FIG. 12 shows a part of an optical device after providing optical elements on the top side of wafer; and

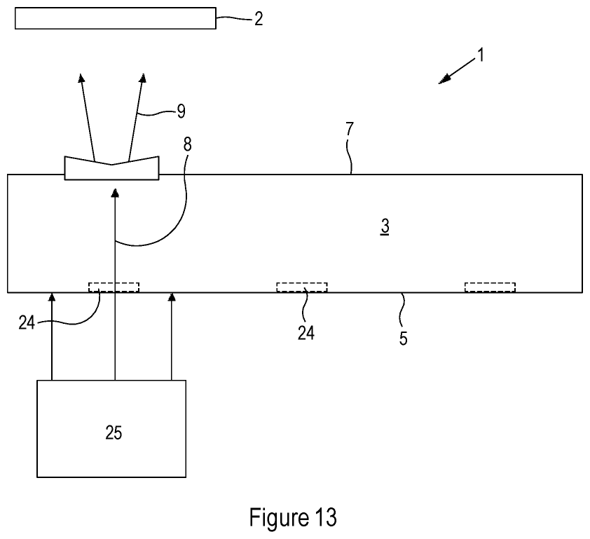

FIG. 13 shows a part of an optical device according to another embodiment, having apertures on the bottom side of the wafer instead of integrated emitters.

### DETAILED DESCRIPTION

FIG. 1 shows a schematic diagram of a part of an optical device 1 and a sensor 2. The optical device 1 comprises a semiconductor wafer 3 with an array of emitters 4 on a bottom surface 5 of the wafer 3. An optical component 6 is located on the top surface 7 of the wafer 3. The optical component 6 may be a quadrant prism and is configured to split the light 8 emitted by an associated emitter 4. The split light beams 9 are received by the sensor in order to determine the alignment between the optical component 6 and the associated emitter 4. The wafer 3 also comprises fiducial markers 10 and 11 on the bottom 5 and top 7 surfaces of the wafer 3, which can be used to align the optical component 6 with the associated emitter 4 when forming the optical component on the wafer 3. The sensor 2 is located in the far field (FF) of the optical component 6, to avoid near field effects.

A method of fabricating an optical device, such as the optical device of FIG. 1 may comprise the following steps in the following order:
1) Align and print fiducial markers on both top and bottom sides of a wafer e.g. using a photolithography process.
2) Fabricate bottom emission VCSEL array on the bottom side of the wafer using the fiducial markers on the same side for alignment.
3) Fabricate optical components, such as quadrant refractive, diffractive or metasurface optics (e.g. nanowires), on the top side of the wafer, using fiducial markers on the top side for alignment. The optical components are aligned to the VCSEL emitters on the back side.
4) Power on emitters such that their output beams propagate through the optical components. By examining the transmitted beam pattern at far field, the misalignment is measured between the beam and the optics.
5) Offset the reticle/mask of the fabrication tool w.r.t. the fiducial markers to compensate for measured misalignment. High alignment accuracy can be achieved in a subsequent photo process for providing optical elements e.g. by patterning integrated micro-/nano-optics.

FIG. 2 shows an example of a light distribution 12 in the sensor plane 13. If the light intensity in each quadrant is the same, then the optical component 6 is perfectly aligned with the underlying emitter 4.

FIG. 3 shows a graph of the normalised power difference between two beams from an emitter that have been split by the optical component as a function of the emitter offset (relative to the optical component). As an example, from FIG. 2, the power of the summed two section beams on the right is P1, and the power of the summed two section beams on the left is P2. As can be seen from the graph in FIG. 3, there is a substantially linear behaviour between the difference in power and the offset. When the offset is zero (i.e. when the optical component and the associated emitter are perfectly aligned) the power difference also goes to zero because the beams are evenly split.

FIG. 4 shows a part of an optical device 1 comprising a wafer 3 comprising an emitter 4 on the bottom surface 5 and an optical component 6 for measuring the alignment between the emitter 4 and the component 6 on the top (emissive) surface 7. Similar or equivalent features in different figures have been given the same reference numerals to aid understanding and are not intended to limit the illustrated embodiments. The optical component 6 is a quadrant prism for splitting the emitted light beam from the emitter 4 in four.

FIG. 5 shows an optical component 6 being a diffractive element comprising an opaque square 14 with a transparent cross 15 in the middle. An outline 16 of a laser beam from an associated emitter in the plane of the optical element 6 is shown. The outline 16 is not centred on the optical element 6, which means that there is some misalignment between the optical element 6 and the associated emitter. After the offset (the alignment) has been determined, the fabrication tool can be adjusted to cancel the offset when populating the wafer with other optical elements, which are part of the finished device. For example, the fabrication tool may apply a displacement to the wafer relative to fiducial markers on the top and/or bottom surface to negate the offset between the optical component 6 and the associated emitter, so that there is no or little offset between new optical elements and their associated emitters.

FIG. 6 shows an alternative optical component 6 being a diffractive element. The optical component 6 comprises a transparent square 17 with an opaque cross 18 in middle.

FIG. 7 shows three graphs of the resulting intensity distribution in the far field from a diffractive element such as the diffractive element of the optical component in FIG. 5. In the first graph (top left), there is no misalignment (zero offset) between the optical component and the associated emitter. Hence, the resulting plot is symmetrical along the x-axis and y-axis. In the second graph (top right) there is a 1 μm offset along the x-axis between the optical component and the associated emitter. This provides a difference in the amplitude of the side lobes in the graph. In particular, the right side lobe 19 has a greater amplitude than the left side lobe 20. Since there is no offset along the y-axis, the graph is still symmetrical about the x-axis. In the third graph (bottom left) there is a 3 μm offset along the x-axis and along the y-axis. This causes the light distribution to shift diagonally (down and to the right).

FIG. 8 shows cross sectional plots of the 2D graphs of FIG. 7. In the first plot (top left), there is no misalignment, and the main lobe and side lobes are symmetrical. In the second plot (top right), the right side lobe 19 is greater than the left side lobe 20 due to the 1 μm offset along the x-axis. In the third plot (bottom left), both the main lobe and the side lobes are skewed due to the offset along the x-axis and along the y-axis. Hence, these plots can be used to determine the alignment between the optical component and the associated emitter.

FIG. 9 is a schematic diagram of an optical element 6 comprising nanowires 21 arranged to at least partly mode convert a TEM₀₀ laser beam to a TEM₁₁ laser beam. The nanowires 21 are arranged in quadrants, wherein nanowires 21 in neighbouring quadrants are arranged perpendicularly to each other. For example, the nanowires 21 in the top left quadrant of the optical element 6 are arranged vertically (along the y-axis), and the nanowires 21 in the top right quadrant are arranged horizontally (along the x-axis). The nanowires 21 are arranged such that the emitted laser beam is perpendicular (along the z-axis) to the nanowires 21. The linewidth can be about 400 nm and the length about 11 μm based on the resolution of a deep ultraviolet (DUV) stepper and the polarization conversion efficiency of nanowires.

FIG. 10 shows the intensity distribution of the TEM₀₀ mode and the TEM₁₁ mode. As can be seen, the TEM₁₁ mode has four amplitude peaks (A, B, C and D). The relative amplitudes of the four peaks of the TEM₁₁ mode can be used to determine the alignment between the optical component and the associated emitter.

FIG. 11 shows the power difference between pairs of peaks of the TEM₁₁ mode plotted against the offset of optical component comprising nanowires, such as the optical component illustrated in FIG. 9. In this example, the power of the two peaks on the right (B and D) is summed and subtracted from the sum of the power of the two peaks on the left (A and C). As can be seen from the graph, the absolute power difference increases with offset.

FIG. 12 shows a schematic diagram of a part of an optical device 1. After the alignment has been determined, an array of (new) optical elements 22 corresponding to at least a part of the array of emitters 4 can be provided. The optical elements 22 can be aligned relative to the fiducial markers 10 or 11 while taking any offset between the optical component 6 and the associated emitter 4 into account. After the optical elements 22 are provided, the wafer 3 can be diced as indicated by the dashed line 23 to remove the optical component 6 and associated emitter 4, leaving only the new optical elements 22 and their associated emitters 4. The optical components 6 may thereby be used for alignment purposes and then removed from the final device.

In other embodiments the optical components 6 and the optical elements 22 may be provided during the same process steps, without determining the alignment inbetween. In this case, the alignment may be determined afterwards for quality control (QC). Wafers with an alignment outside a predetermined threshold value may be discarded.

The proposed solution can also be applied to the fabrication process for making double sided passive optical structures, by replacing the emitter with an aperture on one side of the wafer, and instead using e.g. an external plane wave light source (e.g. a collimated light source) at normal incident angle to the aperture.

FIG. 13 shows a part of an optical device 1 comprising an array of apertures 24. The one or more optical components 6 (e.g. quadrant optics) are provided on the top side 7 over associated apertures 24 on the bottom side 5. An external emitter (e.g. a collimated light source) 25 emits light 8, which is transmitted through the aperture 24. The light 8 then interacts with the optical element 6 and is split into beams 9, which are received by the sensor 2. The received light 9 can then be used to determine the alignment between the array of apertures 24 and the one or more optical components 6.

Although specific embodiments have been described above, the claims are not limited to those embodiments. Each feature disclosed may be incorporated in any of the described embodiments, alone or in an appropriate combination with other features disclosed herein.

Reference Numerals

| | |
|---|---|
| 1 | Optical device |
| 2 | Sensor |
| 3 | Wafer |
| 4 | Emitter |
| 5 | Bottom side |
| 6 | Optical component |
| 7 | Top side |
| 8 | Emitted light |
| 9 | Split light |
| 10 | Fiducial marker |
| 11 | Fiducial marker |
| 12 | Light distribution |
| 13 | Sensor plane |
| 14 | Opaque square |
| 15 | Transparent cross |
| 16 | Beam outline |
| 17 | Transparent square |
| 18 | Opaque cross |
| 19 | Side lobe |
| 20 | Side lobe |
| 21 | Nanowires |
| 22 | Optical element |
| 23 | Dashed line for dicing |
| 24 | Aperture |
| 25 | External emitter |

1. A method of making an optical device, the method comprising:
providing a semiconductor wafer;
providing an array of emitters located on a first side of the wafer;
providing one or more optical components on a second, opposite side of the wafer, wherein the or each optical component is arranged to split light from an associated emitter of the array of emitters;
emitting light with the associated emitter;
receiving light emitted by the associated emitter and transmitted through the optical component on the second side of the wafer; and
determining an alignment between the one or more optical components and the array of emitters from the received light.

2. A method of making an optical device, the method comprising:
providing a semiconductor wafer;
providing an array of apertures located on a first side of the wafer;
providing one or more optical components on a second, opposite side of the wafer, wherein the or each optical component is arranged to split light transmitted through an associated aperture of the array of apertures;
emitting light through the associated aperture from the first side of the wafer;
receiving light transmitted through the associated aperture and through the optical component on the second side of the wafer; and
determining an alignment between the one or more optical components and the array of apertures from the received light.

3. A method according to claim 1, further comprising adjusting a position of a fabrication tool relative to the wafer based on the determined alignment, and fabricating with the fabrication tool an array of optical elements on the second side of the wafer and aligned with the array of emitters or apertures on the first side of the wafer.

4. A method according to claim 1, further comprising, before the step of determining the alignment, fabricating with a fabrication tool an array of optical elements on the second side of the wafer and aligned with the array of emitters or apertures on the first side of the wafer.

5. A method according to claim 4, further comprising repeating the method to provide a plurality of optical devices on respective semiconductor wafers and, after the step of determining, when the alignment of a wafer is below a predetermined threshold value, discarding at least a part of the wafer.

6. A method according to claim 1, wherein the or each optical component comprises an optical quadrant component for separating the emitted light into four beams.

7. A method according to claim 6, wherein the quadrant component comprises a quadrant prism.

8. A method according to claim 1, wherein the or each optical component comprises a diffracting element comprising an opaque square with a transparent cross.

9. A method according to claim 1, wherein the or each optical component comprises a diffracting element comprising a transparent square with an opaque cross.

10. A method according to claim 1, wherein the or each optical component comprises a metasurface comprising nanowires arranged to mode convert at least a part of the emitted light from a first mode to a second mode.

11. A method according to claim 1, wherein at least two optical components are provided and the step of determining an alignment comprises determining a rotational alignment between the array of emitters or apertures and the optical components.

12. A method according to claim 1, further comprising providing a first set of fiducial markers on the first side of the wafer, and a second set of fiducial markers on the second side of the wafer, wherein the step of providing the array of emitters or apertures comprises aligning the array of emitters or apertures with the first set of fiducial markers, and wherein the step of providing the one or more optical components comprises aligning the or each optical component with the second set of fiducial markers.

13. A method according to claim 1, further comprising dicing the wafer such that the one or more of the optical components are removed from the wafer.

14. A semiconductor wafer for making an optical device, the wafer comprising:
an array of emitters or apertures on a first side of the wafer;
one or more optical components on a second, opposite side of the wafer, wherein the or each optical component is arranged to split light from an associated emitter or aperture of the array of emitters or apertures in order to determine an alignment between the one or more optical components and the array of emitters or apertures.

15. A semiconductor wafer according to claim 14, wherein the or each optical component comprises one of a quadrant component, a diffractive element and a metasurface comprising nanowires.
